(19) United States
(12) Patent Application Publication
(10) Pub. No.: US 2020/0013596 A1
(43) Pub. Date: Jan. 9, 2020

(54) PLASMA PROCESS MONITORING APPARATUS AND PLASMA PROCESSING APPARATUS COMPRISING THE SAME

(71) Applicant: INDUSTRY-ACADEMIC COOPERATION FOUNDATION, YONSEI UNIVERSITY, Seoul (KR)

(72) Inventor: Il Gu YUN, Seoul (KR)

(73) Assignee: INDUSTRY-ACADEMIC COOPERATION FOUNDATION, YONSEI UNIVERSITY, Seoul (KR)

(21) Appl. No.: 16/459,833

(22) Filed: Jul. 2, 2019

(30) Foreign Application Priority Data
Jul. 3, 2018 (KR) 10-2018-0076887

(51) Int. Cl. H01J 37/32; H01L 21/67

(52) U.S. Cl. CPC H01J 37/32972; H01J 2237/3341; H01J 2237/3321; H01L 21/67253

(57) ABSTRACT

A plasma process monitoring device includes a first selection area light transmitting part disposed to face a first viewport disposed on one side of a chamber and provided with a plurality of first selective light blocking parts for selectively blocking plasma light emitted through the first viewport, a second selection area light transmitting part disposed to face a second viewport disposed on the other side of the chamber and provided with a plurality of second selective light blocking parts for selectively blocking plasma light emitted through the second viewport, and a monitor for obtaining plasma light information on areas where plasma light transmitted through at least one of the first selective light blocking parts and plasma light transmitted through at least one of the second selective light blocking parts intersect, and monitoring uniformity of plasma formed in the chamber for each area based on the plasma light information.

### CROSS-REFERENCE TO RELATED APPLICATION

This application claims priority to Korean Patent Application No. 10-2018-0076887, filed on Jul. 3, 2018 in the Korean Intellectual Property Office, the disclosure of which is incorporated herein by reference.

### BACKGROUND OF THE DISCLOSURE

### Field of the Disclosure

The present disclosure relates to a plasma process monitoring device for detecting an abnormal plasma state in a plasma process used in a process for etching or depositing a semiconductor and a plasma processing apparatus including the plasma process monitoring device.

### Description of the Related Art

A semiconductor wafer or a substrate for various display devices (hereinafter referred to as a substrate) can be fabricated by forming a thin film on a substrate and repeating a substrate processing process of partially etching the thin film.

In general, the process of forming a thin film is performed using chemical vapor deposition (CVD) or plasma-enhanced chemical vapor deposition (PECVD). In this case, a plasma apparatus used in plasma-enhanced chemical vapor deposition includes a chamber providing a reaction space, a gas feeder for feeding a reaction gas to the chamber, a power supply for supplying power to the gas feeder, and a chuck on which a substrate is placed.

To form a thin film of uniform thickness in plasma-enhanced chemical vapor deposition, it is very important to observe the state of plasma. However, in the case of most conventional plasma process monitoring devices, a total concentration of plasma distributed in a chamber is observed. Thus, when plasma is intensively formed in a specific region of a chamber, it is impossible to measure the uniformity of the plasma in real time.

To solve this problem, a plasma process monitoring device including an array-type sensor has been used to measure plasma uniformity in a chamber. However, such a device is an expensive consumable product, which increases installation and maintenance costs.

### SUMMARY OF THE DISCLOSURE

Therefore, the present disclosure has been made in view of the above problems, and it is an object of the present disclosure to provide a plasma process monitoring device that receives plasma light transmitted through a pair of selection area light transmitting parts installed at different portions of a chamber, discriminating plasma light emitted through viewports for each area of the chamber, and selectively transmitting or blocking the plasma light; measures the intensity of the received plasma light in areas where plasma light intersects; and monitors plasma uniformity in the chamber. Accordingly, when the plasma process monitoring device is used, a substrate of uniform thickness may be fabricated.

In accordance with one aspect of the present disclosure, provided is a plasma process monitoring device including a first selection area light transmitting part disposed to face a first viewport disposed on one side of a chamber, and provided with a plurality of first selective light blocking parts for selectively blocking plasma light emitted through the first viewport; a second selection area light transmitting part disposed to face a second viewport disposed on the other side of the chamber, and provided with a plurality of second selective light blocking parts for selectively blocking plasma light emitted through the second viewport; and a monitor for obtaining plasma light information on areas where plasma light transmitted through at least one of the first selective light blocking parts and plasma light transmitted through at least one of the second selective light blocking parts intersect, and monitoring the uniformity of plasma formed in the chamber for each area based on the plasma light information.

According to one embodiment, the first selection area light transmitting part and the second selection area light transmitting part may be arranged to form an angle of 0° to 180° with respect to each other.

According to one embodiment, the first selection area light transmitting part and the second selection area light transmitting part may be arranged in a direction perpendicular or horizontal to each other, or may be arranged to be inclined with respect to each other.

According to one embodiment, the first selection area light transmitting part may be arranged in parallel with the first viewport disposed in the width direction of the chamber, and the second selection area light transmitting part may be arranged in parallel with the second viewport disposed in the thickness direction of the chamber.

According to one embodiment, the first selection area light transmitting part may be provided with M first selective light blocking parts, the second selection area light transmitting part may be provided with N second selective light blocking parts, and the monitor may obtain plasma light information on MxN areas and may monitor the uniformity of plasma formed in the chamber for each area based on the plasma light information.

According to one embodiment, the first selection area light transmitting part may include a plurality of first selective light blocking parts arranged in parallel in the horizontal or vertical direction, and the second selection area light transmitting part may include a plurality of second selective light blocking parts arranged in parallel in the horizontal or vertical direction.

According to one embodiment, the first selective light blocking parts and the second selective light blocking parts may each be formed in a rectangular shape.

According to one embodiment, the first selection area light transmitting part and the second selection area light transmitting part may each include a transparent LCD panel and a switch. The transparent LCD panel may be provided with one or more LCD unit panels, each of which is divided into at least one area and supplied with power individually. In this case, plasma light may be transmitted only through an area to which power is supplied. The switch may be connected to the transparent LCD panel, and may selectively supply power to each of the areas of each of the LCD unit panels.

According to one embodiment, the first selection area light transmitting part and the second selection area light transmitting part may each include a frame having an opening formed therein and a plurality of shutter members arranged in a line in the frame and responsible for selectively shielding a specific area of the opening.

According to one embodiment, the first selection area light transmitting part and the second selection area light transmitting part may each include a plurality of polarization filter sets, each polarization filter set including two or more polarization filters arranged so as to overlap each other, and configured to selectively transmit plasma light; and a controller for controlling the arrangement angle of at least one of the polarization filters included in each of the polarization filter sets so that plasma light incident on the polarization filter set is selectively blocked.

According to one embodiment, the first selection area light transmitting part and the second selection area light transmitting part may be integrally formed on one surface of the first viewport and one surface of the second viewport, respectively.

According to one embodiment, the plasma light information may include the intensity or quantity of plasma light in areas where plasma light intersects.

According to one embodiment, the monitor may receive information on the intensity or quantity of plasma light in areas where plasma light intersects, may determine whether the intensity or quantity of plasma light falls within a predetermined range, and may determine the uniformity of plasma formed in the chamber for each area.

According to one embodiment, the monitor may include an optical fiber or a measurement sensor to monitor the intensity or quantity of plasma light.

According to one embodiment, the monitor may include an optical emission spectrometer (OES) or a camera.

According to one embodiment, the first selection area light transmitting part and the second selection area light transmitting part may be each connected to a separate monitor or may be connected to one common monitor.

According to one embodiment, the first selection area light transmitting part and the second selection area light transmitting part may each further include a light collector for expanding and focusing an angle of incidence range of plasma light emitted from the inside of the chamber and providing the plasma light to the monitor.

In accordance with another aspect of the present disclosure, provided is a plasma processing apparatus including a chamber in which a plasma process is performed; first and second viewports for emitting plasma light generated in the chamber, wherein the first viewport is disposed on one side of the chamber and the second viewport is disposed on the other side of the chamber; a first selection area light transmitting part disposed to face the first viewport, and provided with a plurality of first selective light blocking parts for selectively blocking plasma light emitted through the first viewport; a second selection area light transmitting part disposed to face the second viewport, and provided with a plurality of second selective light blocking parts for selectively blocking plasma light emitted through the second viewport; and a monitor for obtaining plasma light information on areas where plasma light transmitted through at least one of the first selective light blocking parts and plasma light transmitted through at least one of the second selective light blocking parts intersect, and monitoring the uniformity of plasma formed in the chamber for each area based on the plasma light information.

According to one embodiment, the first selection area light transmitting part and the second selection area light transmitting part may be arranged to form an angle of 0° to 180° with respect to each other.

According to one embodiment, the first selection area light transmitting part may be arranged in parallel with the first viewport disposed in the width direction of the chamber, and the second selection area light transmitting part may be arranged in the vertical or horizontal direction with respect to the first selection area light transmitting part, or the second selection area light transmitting part and the first selection area light transmitting part may be arranged to be inclined with respect to each other.

According to one embodiment, the first selection area light transmitting part may be provided with M first selective light blocking parts, the second selection area light transmitting part may be provided with N second selective light blocking parts, and the monitor may obtain plasma light information on MxN areas and may monitor the uniformity of plasma formed in the chamber for each area based on the plasma light information.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 illustrates the configuration of a plasma process monitoring device according to one embodiment of the present disclosure and a plasma processing apparatus including the plasma process monitoring device;

FIG. 2 is a side view of the plasma process monitoring device and the plasma processing apparatus including the plasma process monitoring device shown in FIG. 1;

FIG. 3 is an enlarged view of a portion of the device shown in FIG. 1, where a viewport is disposed;

FIG. 4 shows a distribution area of plasma light received through the first selection area light transmitting part and the second selection area light transmitting part shown in FIG. 1;

FIG. 5 shows a result of measurement through the plasma processing apparatus shown in FIG. 1 when plasma light is non-uniformly formed in a chamber;

FIG. 6 is a graph showing the intensity of uniform plasma light in the normal range and the intensity of non-uniform plasma light outside the normal range;

FIGS. 7 and 8 show arrangements according to another embodiment of the first selection area light transmitting part and the second selection area light transmitting part shown in FIG. 1;

FIG. 9 illustrates the configuration of the selection area light transmitting parts shown in FIG. 1;

FIG. 10A shows a distribution area of plasma light to be received in a conventional plasma processing apparatus not including selection area light transmitting parts;

FIG. 10B shows a distribution area of plasma light to be received in the plasma processing apparatus shown in FIG. 1;

FIG. 11 illustrates various examples of installation of the selection area light transmitting parts shown in FIG. 1;

FIGS. 12 and 13 show examples of driving the selection area light transmitting parts shown in FIG. 1;

FIGS. 14 and 15 show configurations according to another embodiment of the selection area light transmitting parts included in the device shown in FIG. 1; and

FIG. 16 separately shows sets of polarization filters shown in FIG. 15.

### DETAILED DESCRIPTION OF THE DISCLOSURE

Hereinafter, a plasma process monitoring device and a plasma processing apparatus including the same according to a preferred embodiment will be described in detail with reference to the accompanying drawings. In this specification, the same or similar elements are designated by the same reference numerals. In addition, in the following description of the present disclosure, a detailed description of known functions and configurations incorporated herein will be omitted when it may make the subject matter of the present disclosure unclear. These embodiments are provided to more fully describe the present disclosure to those skilled in the art. Therefore, the shape and size of the components in the following figures may be exaggerated.

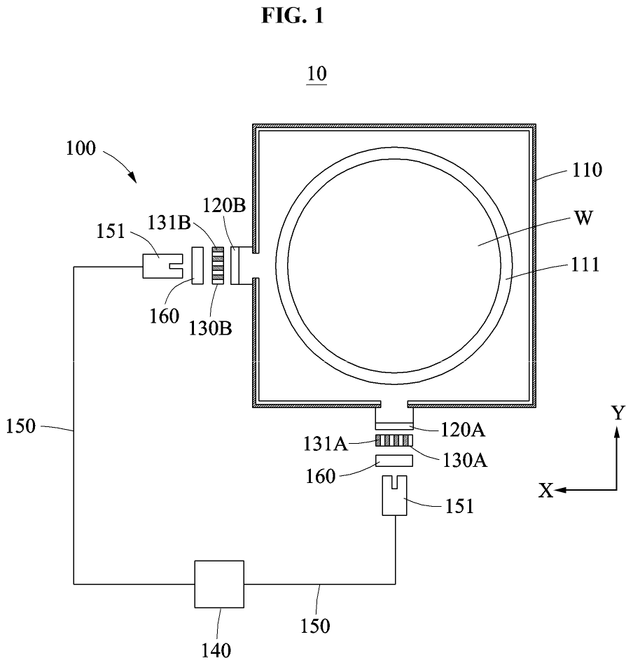

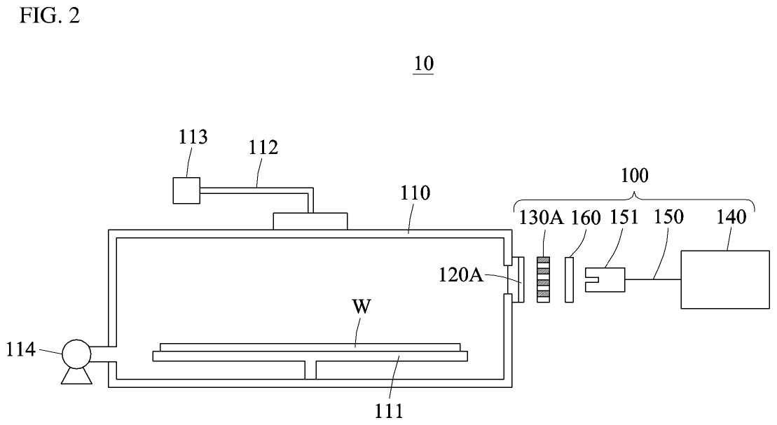

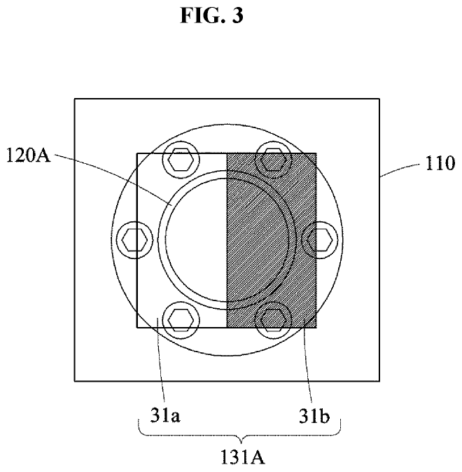

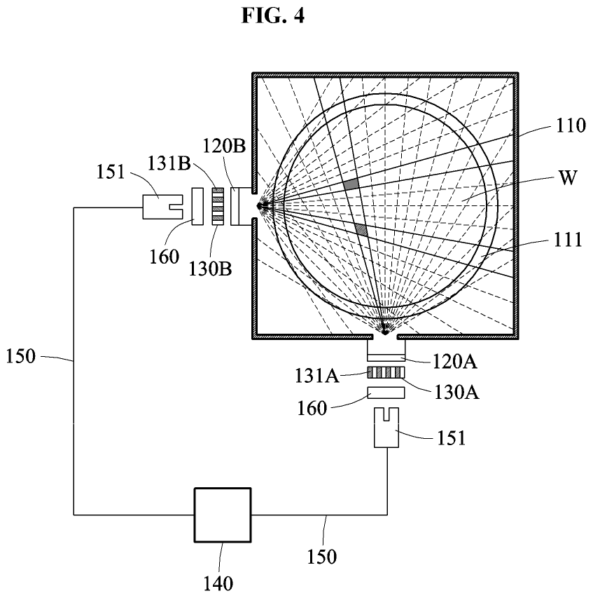

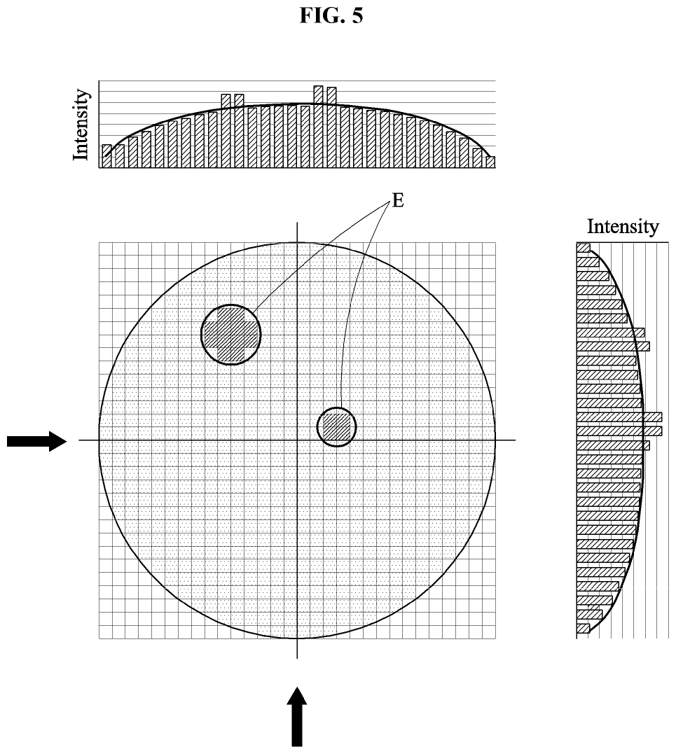

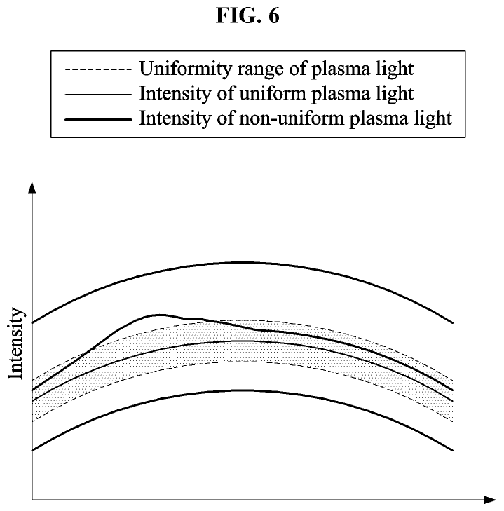

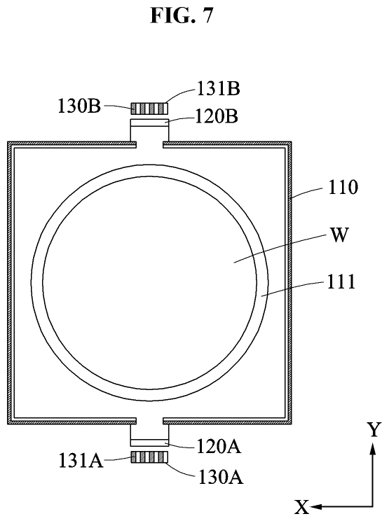

FIG. 1 illustrates the configuration of a plasma process monitoring device according to one embodiment of the present disclosure and a plasma processing apparatus including the plasma process monitoring device; FIG. 2 is a side view of the plasma process monitoring device and the plasma processing apparatus including the plasma process monitoring device shown in FIG. 1; FIG. 3 is an enlarged view of a portion of the device shown in FIG. 1, where a viewport is disposed; FIG. 4 shows a distribution area of plasma light received through the first selection area light transmitting part and the second selection area light transmitting part shown in FIG. 1; FIG. 5 shows a result of measurement through the plasma processing apparatus shown in FIG. 1 when plasma light is non-uniformly formed in a chamber; and FIG. 6 is a graph showing the intensity of uniform plasma light in the normal range and the intensity of non-uniform plasma light outside the normal range.

As shown in FIGS. 1 to 6, a plasma process monitoring device 100 is installed in a chamber 110 provided with a plurality of viewports 120A and 120B, and includes a first selection area light transmitting part 130A, a second selection area light transmitting part 130B, and a monitor 140.

The first selection area light transmitting part 130A may be disposed to face the first viewport 120A disposed on one side of the chamber 110, and may be provided with a plurality of first selective light blocking parts 131A for selectively blocking plasma light emitted through the first viewport 120A.

When the first selection area light transmitting part 130A is disposed on one side of the chamber, e.g., in the X axis direction (Y-axis direction is also possible), plasma light generated in the chamber 110 may be incident in a direction perpendicular to the first selection area light transmitting part 130A, i.e., in the Y-axis direction. In addition, plasma light generated in the chamber 110 may be incident in any direction within the range of 0° to 180°, rather than in the vertical direction. In this case, when the first viewport 120A is divided into several areas by the first selective light blocking parts 131A so that plasma light is alternately blocked for each area, the intensity or quantity of plasma light in the chamber 110 may be measured for each area in the Y-axis direction or in other directions. In this case, the size of the first selective light blocking parts 131A is not limited, but the first selective light blocking parts 131A are preferably formed to have a size such that a minimum amount of plasma light passes therethrough.

The first selective light blocking parts 131A may be arranged in parallel in the horizontal direction or the vertical direction, and each of the first selective light blocking parts 131A may be formed in a rectangular shape. In addition, the first selective light blocking parts 131A are preferably formed so that no gaps are formed therebetween. Consequently, unmeasured regions are prevented from being generated when plasma uniformity is measured.

The second selection area light transmitting part 130B may be disposed to face the second viewport 120B disposed on the other side of the chamber 110, and may be provided with a plurality of second selective light blocking parts 131B for selectively blocking plasma light emitted through the second viewport 120B.

In this embodiment, the second viewport 120B is disposed at an angle of 90° with respect to the first viewport 120A. However, the second viewport 120B may be disposed at an angle of 0° to 180° with respect to the first viewport 120A. For example, when the chamber 110 is formed to have a large area, the first and second viewports 120A and 120B may be arranged to form an angle of 00 or 180° with respect to each other. That is, the first and second viewports 120A and 120B may be disposed on the same side of the chamber 110, and may be disposed to face each other.

When the second selection area light transmitting part 130B is disposed on the other side of the chamber, e.g., in the Y-axis direction (X-axis direction is also possible), plasma light generated in the chamber 110 may be incident in a direction perpendicular to the second selection area light transmitting part 130B, i.e., in the X-axis direction. In addition, plasma light generated in the chamber 110 may be incident in any direction within the range of 00 to 180°, rather than in the vertical direction, and may be incident in the parallel direction, i.e., in the Y-axis direction. In this case, when the second viewport 120B is divided into several areas by the second selective light blocking parts 131B so that plasma light is alternately blocked for each area, the intensity or quantity of plasma light in the chamber 110 may be measured for each area in the X-axis direction or in other directions (including the Y-axis direction). In this case, the size of the second selective light blocking parts 131B is not limited, but the second selective light blocking parts 131B are preferably formed to have a size such that a minimum amount of plasma light passes therethrough.

The second selective light blocking parts 131B may be arranged in parallel in the horizontal direction or the vertical direction, and each of the second selective light blocking parts 131B may be formed in a rectangular shape. In addition, the second selective light blocking parts 131B are preferably formed so that no gaps are formed therebetween. Consequently, unmeasured regions are prevented from being generated when plasma uniformity is measured.

When plasma light in the chamber 110 is measured for each region in the Y-axis direction through the first selection area light transmitting part 130A and plasma light in the chamber 110 is measured for each region in the X-axis direction through the second selection area light transmitting part 130B, as shown in FIG. 4, the monitor 140 may perform spatial analysis for a region where plasma light intersects when the plasma light is received.

In addition, the first selection area light transmitting part 130A and the second selection area light transmitting part 130B may be arranged to form an angle of 0° to 180° with respect to each other. Here, 0° indicates that the first selection area light transmitting part 130A and the second selection area light transmitting part 130B are arranged in parallel, and 180° indicates that the first selection area light transmitting part 130A and the second selection area light transmitting part 130B are arranged to face to each other. With this arrangement, plasma light generated in the chamber 110 may be incident on the first selection area light transmitting part 130A and the second selection area light transmitting part 130B at any angle of incidence of 00 to 180°.

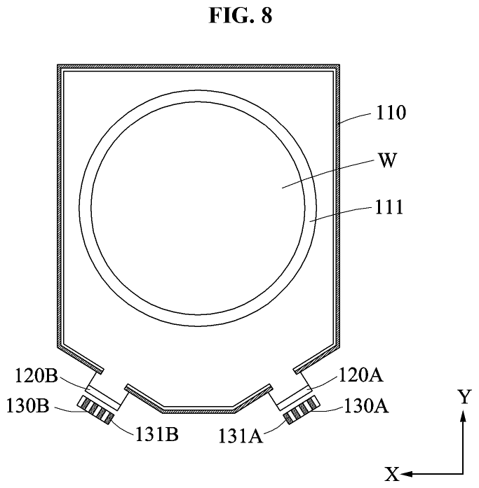

For example, as shown in FIG. 7, the first selection area light transmitting part 130A and the second selection area light transmitting part 130B may be arranged in the horizontal direction, i.e., at an angle of 180°, to face each other. In addition, as shown in FIG. 8, the first selection area light transmitting part 130A and the second selection area light transmitting part 130B may be disposed at an inclined surface of the chamber.

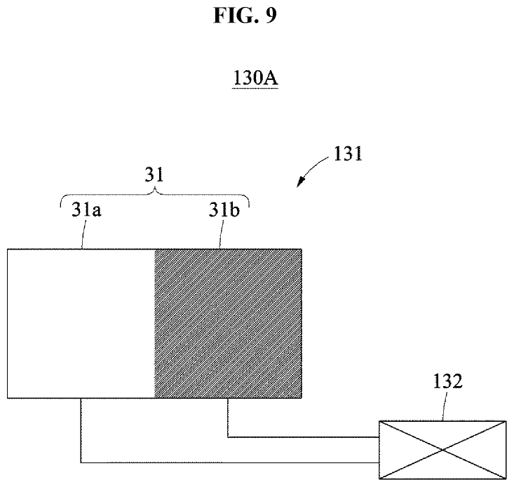

FIG. 9 illustrates the configuration of the selection area light transmitting parts shown in FIG. 1. Referring to FIG. 9, the first selection area light transmitting part 130A and the second selection area light transmitting part 130B may each include a transparent LCD panel 131 and a switch 132. Here, since the first selection area light transmitting part 130A and the second selection area light transmitting part 130B have the same structure and functions, the following description is given on the basis of the first selection area light transmitting part 130A.

The transparent LCD panel 131 may be disposed to face the first viewport 120A. The transparent LCD panel 131 may be provided with one or more LCD unit panels 31, each of which is divided into one or more areas 31a and 31b and supplied with power individually. In this case, plasma light may be transmitted only through an area to which power is supplied.

That is, the transparent LCD panel 131 may be a transparent film containing a liquid crystal material. When power is supplied to the transparent LCD panel 131, a liquid crystal material therein is scattered and light is scattered to adjust coloring, i.e., contrast. In the present disclosure, a simplified LCD panel in which contrast is adjusted only in black is preferably used.

Each of the areas 31a and 31b of each of the LCD unit panels 31 constituting the transparent LCD panel 131 may be individually connected to a power source so that contrast thereof may be adjusted in black. That is, the LCD unit panels 31 serve as the first selective light blocking parts 131A. In FIG. 9, each of the LCD unit panels 31 is divided into two areas 31a and 31b. However, the present disclosure is not limited thereto, and each of the LCD unit panels 31 may be divided into one or more areas. For example, when the LCD unit panel 31 has one area, the transparent LCD panel 131 may be provided with a plurality of LCD unit panels 31, and the LCD unit panels 31 may be connected to each other. Here, the sizes of the areas 31a and 31b of each of the LCD unit panels 31 are not particularly limited. Preferably, the areas 31a and 31b are formed to have a size allowing a minimum amount of plasma light to pass therethrough.

The switch 132 may be connected to the transparent LCD panel 131, and may selectively supply power to each of the areas 31a and 31b of each of the LCD unit panels 31. Accordingly, by controlling the switch 132, the contrast of each of the areas 31a and 31b of each of the LCD unit panels 31 may be individually adjusted. For example, as shown in FIG. 9, when the transparent LCD panel 131 is provided with one LCD unit panel 31, the area of which is divided into two areas 31a and 31b, when power is applied only to the area 31a disposed on the left side of the LCD unit panel 31 through the switch 132, the contrast of each of the area 31a disposed on the left side and the area 31b disposed on the right side is adjusted so that the area 31a becomes transparent and the area 31b becomes black. Consequently, plasma light may be transmitted only through the area 31a, and plasma light may be blocked by the area 31b.

Accordingly, plasma light transmitted through the first viewport 120A is not transmitted through the area 31b disposed on the right side, but is transmitted only through the area 31a disposed on the left side. That is, the amount of light passing through the area 31b disposed on the right side is 0%, and the amount of light passing through the area 31a disposed on the left side is 100%.

The monitor 140 obtains information on plasma light in areas where plasma light passing through at least one of the first selective light blocking parts 131A and plasma light passing through at least one of the second selective light blocking parts 131B intersect, and monitors the uniformity of plasma formed in the chamber 110 for each area based on the obtained plasma light information. Here, the plasma light information may include the intensity and quantity of plasma light in areas where plasma light intersects. In addition, uniformity means that the intensity of plasma light for each area in areas where plasma light intersects falls within a predetermined range. That is, when the intensity of plasma light for each area measured by the monitor 140 falls within a predetermined range, plasma light formed in the chamber 110 may be regarded as uniform. For example, the range of the uniformity of plasma emitted from the center of the chamber 110 is set to 95 to 105, when the plasma intensity of the center of the chamber 110 measured by the monitor 140 is 100, it can be determined that plasma formed in the center of the chamber 110 is uniform.

The monitor 140 may be disposed outside the chamber 110, and may be connected to the first selection area light transmitting part 130A and the second selection area light transmitting part 130B through optical cables 150 provided with optical probes 151. Two monitors 140 may be connected to the first selection area light transmitting part 130A and the second selection area light transmitting part 130B, respectively. However, in this embodiment, a single monitor 140 is provided and connected to the first selection area light transmitting part 130A and the second selection area light transmitting part 130B so that the monitor 140 is disposed therebetween.

Specifically, the optical probes 151 may be provided as a pair, and may be disposed near the first selection area light transmitting part 130A and the second selection area light transmitting part 130B, respectively. In addition, each of the optical probes 151 may be optically connected to the monitor 140 using a pair of the optical cables 150. Accordingly, the monitor 140 may analyze plasma light transmitted through the optical probes 151 and the optical cables 150. For example, the optical cables 150 may be formed of an optical fiber.

The monitor 140 may be a device having an optical fiber and monitoring the intensity or quantity of plasma light, e.g., an optical emission spectrometer (OES). An optical emission spectrometer uses the discontinuous electron energy levels of atoms and ions, and detects light emitted when electrons in a relatively high energy state transit to a low energy state. However, the present disclosure is not limited to an optical emission spectrometer (OES) as the monitor 140, and the monitor 140 may include a camera for monitoring the intensity or quantity of plasma light.

In addition, the monitor 140 may include a measurement sensor for measuring the intensity or quantity of plasma light, and may monitor the intensity or quantity of plasma light.

When the monitor 140 includes a measurement sensor, the monitor 140 may be directly connected to the optical probes 151 without the optical cables 150, i.e., an optical fiber, and may monitor the intensity or quantity of plasma light passing through the first selection area light transmitting part 130A and the second selection area light transmitting part 130B.

When the plasma light of a specific area passes through the first selection area light transmitting part 130A and the second selection area light transmitting part 130B, and the monitor 140 analyzes the transmitted plasma light, it is possible to detect an abnormal plasma state for each area in the chamber 110 and to perform spatial analysis of the plasma state. That is, as shown in FIG. 4, when the monitor 140 receives plasma light passing through the first selection area light transmitting part 130A and incident in the X-axis direction and plasma light passing through the second selection area light transmitting part 130B and incident in the Y-axis direction, areas where plasma light intersects may be displayed in coordinates. When the first and second viewports 120A and 120B are arranged so as to face each other at an angle of 180° instead of being arranged in the vertical direction with respect to each other, the first selection area light transmitting part 130A and the second selection area light transmitting part 130B may be disposed so as to face each other. In this case, when the monitor 140 receives plasma light passing through the first selection area light transmitting part 130A and incident in the X-axis direction and plasma light passing through the second selection area light transmitting part 130B and incident in the X-axis direction, areas where plasma light intersects may be displayed in coordinates.

Accordingly, as shown in FIG. 5, the monitor 140 may display the intensity of plasma light for each coordinate as a map. When plasma light formed inside the chamber 110 is non-uniform, the monitor 140 may receive and compare plasma light information on areas where plasma light intersects, and may output information about non-uniform areas E to the outside. Then, an operator may determine the uniformity of plasma formed inside the chamber 110 for each area by checking the coordinates of non-uniform areas E output through the monitor 140.

For example, as shown in FIGS. 5 and 6, the monitor 140 may receive the intensity of plasma light according to positions, interconnect information on light intensity, and display the obtained results as a graph. In the graph, an arc shape with a convex center portion is observed, indicating that plasma light is concentrated in the center of the chamber 110. When a graph obtained by measuring plasma light falls within a predetermined range, it may be determined that the uniformity of plasma light generated inside the chamber 110 is constant. As shown in FIG. 6, even when a graph for plasma light exhibits an arc shape, when the graph deviates from a predetermined range or when a part of the graph deviates from the predetermined range, the monitor 140 may determine that plasma light generated inside the chamber 110 is non-uniform.

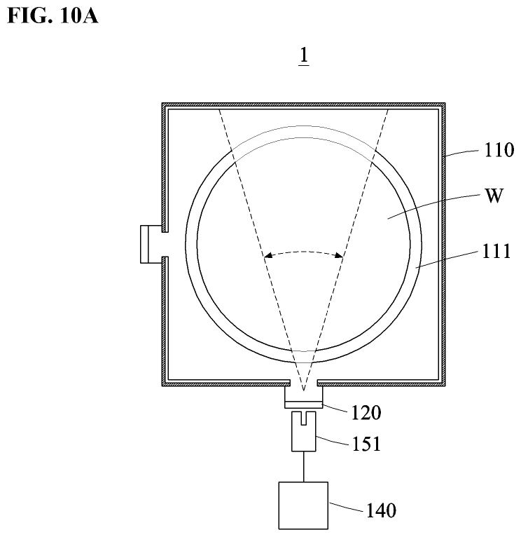

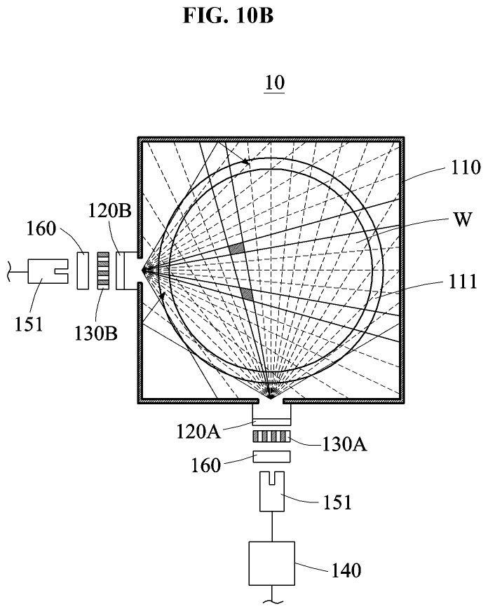

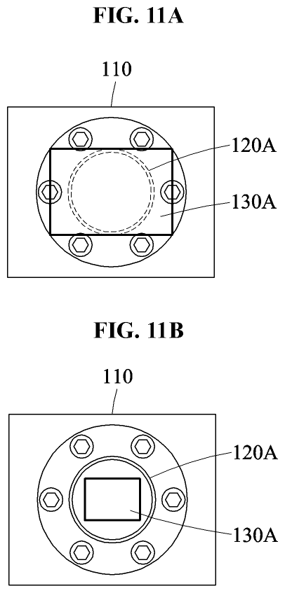

FIG. 10A shows a distribution area of plasma light to be received in a conventional plasma processing apparatus not including selection area light transmitting parts, and FIG. 10B shows a distribution area of plasma light to be received in the plasma processing apparatus shown in FIG. 1.

Referring to FIG. 10B, the first selection area light transmitting part 130A and the second selection area light transmitting part 130B may each further include a light collector 160 for expanding and focusing the angle of incidence range of plasma light emitted from the inside of the chamber 110 and providing the plasma light to the monitor 140.

The light collector 160 may be formed of a specially processed concave lens. In this case, a concave lens may have a structure in which the curvature in the horizontal direction is larger than the curvature in the vertical direction. Accordingly, plasma light emitted from the inside of the chamber 110 may be focused by expanding an angle of incidence range B of the plasma light.

That is, conventionally, as shown in FIG. 10A, only a part of plasma light is collected through the optical cables 150, e.g., an optical fiber, of the monitor 140. However, according to the embodiment of the present disclosure, as shown in FIG. 10B, the light collector 160 is additionally installed in each of the first selection area light transmitting part 130A and the second selection area light transmitting part 130B, and the light collector 160 receives plasma light from a large area inside the chamber 110. Accordingly, analysis of a plasma state may be uniformly performed from the center to the outermost portion of a substrate W, thereby improving performance of analyzing the plasma state. For example, to extend a range of receiving light in the chamber 110, i.e., an angle of incidence range of plasma light, a specially processed concave lens may be inserted between the first selection area light transmitting part 130A and the monitor 140 and between the second selection area light transmitting part 130B and the monitor 140. As a result, a light reception angle may be increased to a remarkable level (approximately 160° or more).

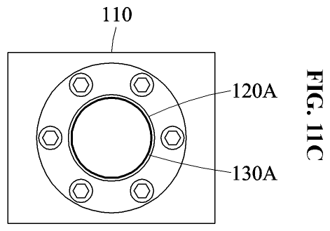

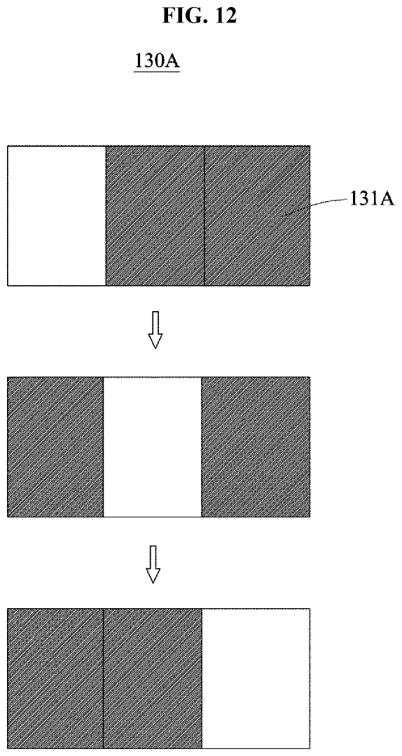

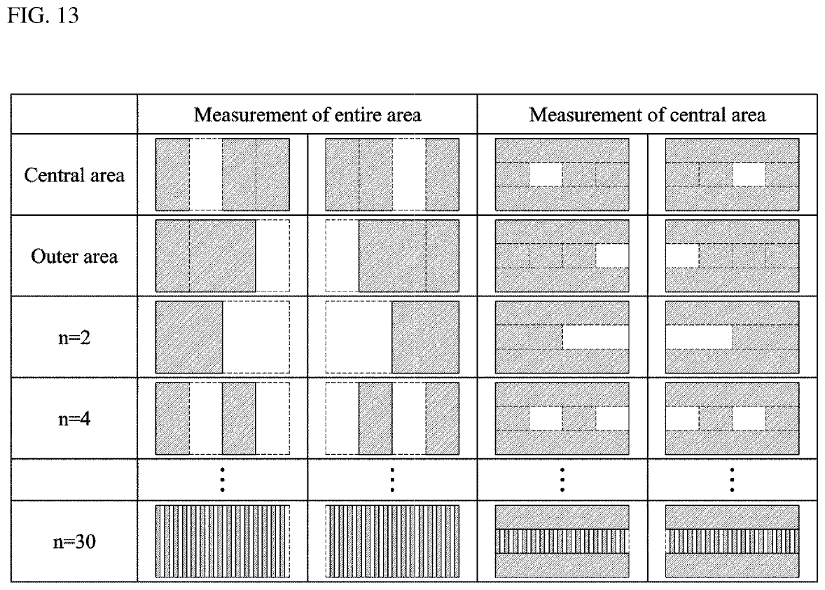

FIG. 11 illustrates various examples of installation of the selection area light transmitting parts shown in FIG. 1, and FIGS. 12 and 13 show examples of driving the selection area light transmitting parts shown in FIG. 1. Here, since the first selection area light transmitting part 130A and the second selection area light transmitting part 130B have the same structure and are driven in the same way, the following description is given on the basis of the first selection area light transmitting part 130A.

As shown in FIG. 11, the first selection area light transmitting part 130A may be formed larger than the first viewport 120A and may be disposed to be spaced from the first viewport 120A (see FIG. 11A), or may be formed smaller than the first viewport 120A and may be disposed on one side of the first viewport 120A (see FIG. 11B). In addition, the first selection area light transmitting part 130A may be formed to have the same size as the first viewport 120A and may be disposed on one side of the first viewport 120A (see FIG. 11C). In this case, the center of the first selection area light transmitting part 130A may be arranged on the same line as the center of the first viewport 120A. When the first selection area light transmitting part 130A is disposed on one side of the first viewport 120A, one side of the first selection area light transmitting part 130A and one side of the first viewport 120A are in contact with each other. Accordingly, the first selection area light transmitting part 130A and the first viewport 120A may be integrally formed using a fastening means such as an adhesive.

The first selection area light transmitting part 130A may be formed so that plasma light is transmitted through at least one of the first selective light blocking parts 131A. For example, as shown in FIG. 12, the first selective light blocking parts 131A may sequentially transmit plasma light in one direction. When plasma light is sequentially transmitted in one direction, changes in the quantity of plasma light may be continuously measured, and thus the uniformity of plasma may be continuously measured.

As shown in FIG. 13, the number (n) of the first selective light blocking parts 131A provided in the first selection area light transmitting part 130A may be varied. In addition, the first selective light blocking parts 131A may be arranged so that the entire area of the chamber 110 or only the central area of the chamber 110 is measured. Here, the reason for measuring only the central area of the chamber 110 is that plasma may be concentrated in the central area of the chamber 110.

For example, as shown in FIG. 13, when the first selection area light transmitting part 130A includes two first selective light blocking parts 131A, the first selective light blocking parts 131A may be formed so that the right and left regions thereof alternately block plasma light. Accordingly, the uniformity of plasma distribution in the chamber 110 may be determined by comparing the intensities of plasma light formed in the left and right regions of the chamber 110.

In addition, when the first selection area light transmitting part 130A includes three first selective light blocking parts 131A, the first selective light blocking parts 131A may be set so that plasma light alternately passes through only the first selective light blocking part 131A on the left side and the first selective light blocking part 131A on the right side. With this setting, measurement may be performed only in the outer area of the chamber 110. In addition, as shown in FIG. 12, by setting the first selective light blocking parts 131A so that the first selective light blocking parts 131A sequentially transmit plasma light, changes in the quantity of plasma light may be continuously measured. In addition, the first selective light blocking parts 131A may be set so that the first selective light blocking parts 131A transmit plasma light in an arbitrary order rather than in a sequential manner.

In addition, when the first selection area light transmitting part 130A includes four first selective light blocking parts 131A, the first selective light blocking parts 131A may be formed so that the odd-numbered first selective light blocking parts 131A and the even-numbered first selective light blocking parts 131A alternately transmit plasma light. As another example, when four first selective light blocking parts 131A are provided, the first selective light blocking parts 131A may be formed so that only the leftmost area and the rightmost area alternately transmit plasma light or the first selective light blocking parts 131A sequentially transmit plasma light. In addition, when four first selective light blocking parts 131A are provided, the first selective light blocking parts 131A may be set so that the first selective light blocking parts 131A transmit plasma light in an arbitrary order rather than in a sequential manner.

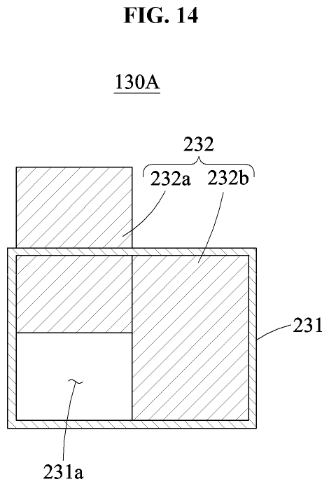

FIG. 14 shows a configuration according to another embodiment of the selection area light transmitting parts included in the device shown in FIG. 1.

As shown in FIG. 14, the first selection area light transmitting part 130A and the second selection area light transmitting part 130B may each include a frame 231 and shutter members 232. Here, since the first selection area light transmitting part 130A and the second selection area light transmitting part 130B have the same structure and are driven in the same way, the following description is given on the basis of the first selection area light transmitting part 130A.

The frame 231 may be disposed to face the first viewport 120A, and an opening 231a may be formed in one side thereof.

A plurality of shutter members 232 may be arranged in a line in the frame 231 and may selectively shield a specific area of the opening 231a. That is, the shutter members 232 may serve as the first selective light blocking parts 131A, and a drive motor for rotating or linearly moving the shutter members 232 may be installed on one side of the shutter members 232. Accordingly, as shown in FIG. 14, when the frame 231 is provided with two shutter members 232a and 232b, when the shutter member 232b disposed on the right side is driven by the drive motor, the opening 231a disposed on the right side is shielded. Consequently, plasma light is not transmitted through the opening 231a disposed on the right side, but plasma light is transmitted only through the opening 231a disposed on the left side. The sizes of the shutter members 232a and 232b are not particularly limited, and the shutter members 232a and 232b are preferably formed to have a size allowing a minimum amount of plasma light to pass therethrough.

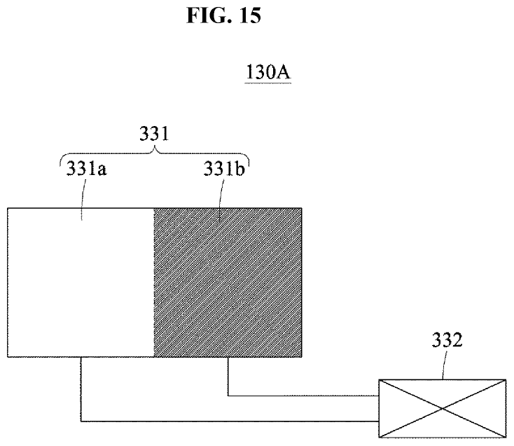

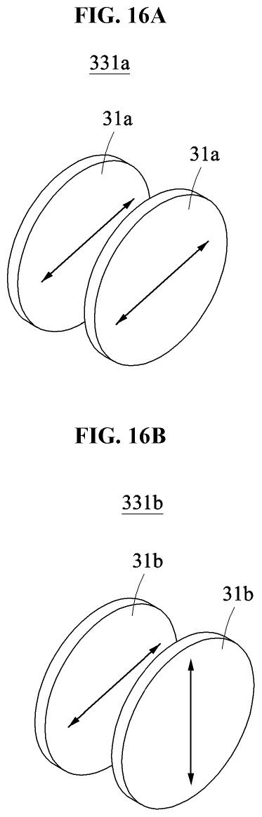

FIG. 15 shows a configuration according to another embodiment of the selection area light transmitting parts included in the device shown in FIG. 1, and FIG. 16 separately shows sets of polarization filters shown in FIG. 15.

As shown in FIGS. 15 and 16, the first selection area light transmitting part 130A and the second selection area light transmitting part 130B may each include polarization filter sets 331 and a controller 332. Here, since the first selection area light transmitting part 130A and the second selection area light transmitting part 130B have the same structure and are driven in the same way, the following description is given on the basis of the first selection area light transmitting part 130A.

Referring to FIGS. 15 and 16, the polarization filter set 331a and the polarization filter set 331b may include two or more polarization filters 31a arranged to overlap each other and two or more polarization filters 31b arranged to overlap each other, respectively. In addition, the polarization filter sets 331a and 331b may be formed to selectively transmit plasma light. The polarization filters 31a and 31b may transmit only light oscillating in a specific direction among light oscillating in various directions.

The controller 332 may selectively block plasma light transmitted through the polarization filters 31a and 31b by controlling the angles of the polarization filters 31a and 31b included in the polarization filter sets 331. Specifically, as shown in FIG. 16, when one polarization filter set 331 is provided in the left side and the other polarization filter set 331 is provided in the right side, when the arrangement angle of each of two polarization filters 31b included in the polarization filter set 331b disposed on the right side is adjusted by the controller 332 so that the polarization filters 31b are perpendicular to each other (e.g., the polarization filters 31b are arranged so that one transmits vertically polarized light and the other transmits horizontally polarized light), plasma light incident on the polarization filter set 331b disposed on the right side may be blocked. When the arrangement angle of each of two polarization filters 31a included in the polarization filter set 331a disposed on the left side is adjusted by the controller 332 so that the polarization filters 31a are parallel to each other (e.g., the polarization filters 31a are arranged so that both of the polarization filters 31a transmit vertically polarized light or both of the polarization filters 31a transmit horizontally polarized light), plasma light incident on the polarization filter set 331a disposed on the left side may be transmitted (see FIGS. 16A and 16B).

As described above, in the plasma process monitoring device 100, the first selection area light transmitting part 130A for selectively transmitting or blocking plasma light emitted through the first viewport 120A and the second selection area light transmitting part 130B for selectively transmitting or blocking plasma light emitted through the second viewport 120B are arranged to form an angle of 0° to 180° with respect to each other. With this configuration, the uniformity of plasma formed in the chamber 110 during a plasma process may be monitored for each area of the chamber 110.

In addition, when it is confirmed by the monitor 140 that the uniformity of plasma is deteriorated, plasma process conditions may be controlled to optimize a plasma processing environment so that plasma distribution is uniform. Thus, an excellent and reliable semiconductor substrate W may be fabricated.

In addition, conventionally, to measure the uniformity of plasma formed in the chamber 110 for each area, an expensive sensor such as a sensor having an array structure is required. However, according to the present disclosure, the relatively inexpensive first selection area light transmitting part 130A and the relatively inexpensive second selection area light transmitting part 130B are used to measure plasma uniformity for each area of the chamber, thereby reducing initial installation costs.

In addition, since a sensor having an array structure for measuring the quantity of plasma light is a consumable item, cost is continuously incurred. However, according to the present disclosure, since an optical emission spectrometer (OES) as a monitoring device may be used semi-permanently, no additional cost is incurred.

As shown in FIGS. 1 to 16, a plasma processing apparatus 10 including the plasma process monitoring device 100 includes the chamber 110, the first viewport 120A, the second viewport 120B, the first selection area light transmitting part 130A, the second selection area light transmitting part 130B, and the monitor 140. In this embodiment, differences from the above-described embodiments will be mainly described.

The chamber 110 is a place in which a plasma process is performed, and a chuck 111 on which the substrate W is placed may be installed therein. Here, the substrate W may include a semiconductor substrate, a metal substrate, or a glass substrate. The substrate W may be treated using an etching process, a chemical vapor deposition process, an ashing process, or a washing process, without being limited thereto.

A gas feeder 113 connected to the inside of the chamber 110 via a gas supply pipe 112 is provided at one side of the chamber 110. With this configuration, a reaction gas for generating plasma may be supplied to the chamber 110. An inert gas such as argon (Ar) or nitrogen (N₂) may be used as the reaction gas.

A vacuum unit 114 may be connected to one side of the chamber 110 to form a vacuum in the chamber 110. The vacuum unit 114 may include a vacuum pump, a control valve for controlling pressure, and the like.

When the first viewport 120A is disposed in the chamber 110, the first viewport 120A may be arranged in the X-axis direction. The first viewport 120A may transmit plasma light generated in the chamber 110 to the outside. Specifically, the first viewport 120A may be provided with a window for checking the inside of the chamber 110 in which an etching process, a deposition process, or the like is performed. Accordingly, since plasma light formed in the chamber 110 may be transmitted to the outside through the first viewport 120A, it may be confirmed that plasma is properly formed during an etching process, a deposition process, or the like, and it may be externally confirmed whether the substrate W is maintained in a stable state during the process.

When the second viewport 120B is disposed in the chamber 110, the second viewport 120B may be arranged in the Y-axis direction, i.e., in a direction perpendicular to the first viewport 120A, or may be arranged in the X-axis direction, i.e., in a direction parallel to the first viewport 120A. The second viewport 120B may transmit plasma light generated in the chamber 110 to the outside. The arrangement of the first and second viewports 120A and 120B is not limited thereto, and the first and second viewports 120A and 120B may be arranged at various angles within an angle range of 0° to 180°. Here, the second viewport 120B has the same structure as the first viewport 120A, and thus a detailed description thereof will be omitted.

The first selection area light transmitting part 130A may be disposed to face the first viewport 120A disposed on the chamber 110, and may be provided with the first selective light blocking parts 131A for selectively blocking plasma light emitted through the first viewport 120A.

The second selection area light transmitting part 130B may be disposed to face the second viewport 120B disposed on the chamber 110, and may be provided with the second selective light blocking parts 131B for selectively blocking plasma light emitted through the second viewport 120B.

The first selection area light transmitting part 130A and the second selection area light transmitting part 130B may each include the transparent LCD panel 131 and the switch 132, may each include the frame 231 and the shutter members 232, and may each include the polarization filter sets 331 and the controller 332. Since the configuration of the first selection area light transmitting part 130A and the second selection area light transmitting part 130B is the same as that described above, a detailed description thereof will be omitted.

The monitor 140 obtains the intensity or quantity of plasma light of areas where plasma light passing through at least one of the first selective light blocking parts 131A and plasma light passing through at least one of the second selective light blocking parts 131B intersect, and determines whether the obtained intensity or quantity of plasma light falls within a predetermined range and determines the uniformity of plasma formed in the chamber 110 for each area.

The operation of the plasma processing apparatus 10 including the plasma process monitoring device will be described with reference to FIGS. 1 to 16.

First, when the substrate W is placed on the chuck 111 installed inside the chamber 110, vacuum is formed inside the chamber 110 by operation of the vacuum unit 114. In this state, a reaction gas is supplied into the chamber 110 by the gas feeder 113. Then, when high frequency current is applied to the inside of the chamber 110, the reaction gas is transformed into plasma, and an etching process, a deposition process, or the like may be performed under these conditions.

When plasma is formed, light generated in plasma is transmitted to the first selection area light transmitting part 130A and the second selection area light transmitting part 130B through the first and second viewports 120A and 120B. In this case, since the first selection area light transmitting part 130A is divided into several compartments in the X-axis direction by the first selective light blocking parts 131A, by selectively shielding the first selective light blocking parts 131A, the intensity or quantity of plasma light in the chamber 110 may be measured for each area in the Y-axis or X-axis direction. In this case, plasma light generated in the chamber 110 may be incident at any angle within a range of 0° to 180°, rather than in the vertical direction. In addition, since the second selection area light transmitting part 130B is divided into several compartments in the Y-axis direction by the second selective light blocking parts 131B, by selectively shielding the second selective light blocking parts 131B, the intensity or quantity of plasma light in the chamber 110 may be measured for each area in the Y-axis or X-axis direction. In this case, plasma light generated in the chamber 110 may be incident at any angle within a range of 0° to 180°, rather than in the vertical direction.

Accordingly, the monitor 140 may receive plasma light information for each area in the Y-axis direction and plasma light information for each area in the X-axis direction through the optical probes 151 and the optical cables 150. As shown in FIG. 5, when the monitor 140 receives plasma light information on areas where plasma light intersects, plasma intensity for each area in the chamber 110 may be measured using intersecting points, and the uniformity of plasma formed in the chamber 110 may be confirmed by determining whether plasma intensity for each area falls in a predetermined range.

By confirming plasma uniformity for each area through the above process, the deposition uniformity or etching uniformity of the substrate W formed in the chamber 110 may be confirmed. That is, when plasma intensity is biased in one direction in the chamber 110, the deposition process or etching process of a portion of the substrate W disposed in an area where plasma intensity is high rapidly progresses, and the deposition process or etching process of a portion of the substrate W disposed in other areas progress slowly. Consequently, the substrate W having a uniform thickness may not be formed.

Therefore, when it is confirmed by the monitor 140 that the uniformity of plasma is deteriorated, plasma process conditions may be controlled to optimize a plasma processing environment. Thus, an excellent and reliable semiconductor substrate W may be fabricated.

According to the present disclosure, a first selection area light transmitting part for selectively transmitting or blocking plasma light emitted through a first viewport is disposed in the X-axis direction, and a second selection area light transmitting part for selectively transmitting or blocking plasma light emitted through a second viewport is disposed in the Y-axis direction, i.e., in a direction perpendicular to the first selection area light transmitting part or is disposed in the X-axis direction, i.e., in a direction parallel to the first selection area light transmitting part. With this configuration, the uniformity of plasma formed in a chamber during a plasma process can be monitored for each area of the chamber.

In addition, when it is confirmed by a monitor that the uniformity of plasma is deteriorated, plasma process conditions can be controlled to optimize a plasma processing environment so that plasma distribution is uniform. Thus, an excellent and reliable semiconductor substrate can be fabricated.

In addition, conventionally, to measure the uniformity of plasma formed in a chamber for each area, an expensive sensor such as a sensor having an array structure is required. However, according to the present disclosure, a relatively inexpensive first selection area light transmitting part and a relatively inexpensive second selection area light transmitting part are used to measure plasma uniformity for each area of a chamber, thereby reducing initial installation costs.

In addition, since a sensor having an array structure for measuring the quantity of plasma light is a consumable item, cost is continuously incurred. However, according to the present disclosure, since an optical emission spectrometer (OES) as a monitoring device can be used semi-permanently, no additional cost is incurred.

Hereinafter, the present disclosure has been described in detail with reference to the preferred examples. However, these examples are provided for illustrative purposes only and should not be construed as limiting the scope and spirit of the present disclosure. In addition, it will be apparent to those skilled in the art that various changes and modifications may be made without departing from the spirit and scope of the present disclosure. Therefore, the scope of protection of the present disclosure should be construed according to the following claims.

What is claimed is:

1. A plasma process monitoring device, comprising:
a first selection area light transmitting part disposed to face a first viewport disposed on one side of a chamber, and provided with a plurality of first selective light blocking parts for selectively blocking plasma light emitted through the first viewport;
a second selection area light transmitting part disposed to face a second viewport disposed on the other side of the chamber, and provided with a plurality of second selective light blocking parts for selectively blocking plasma light emitted through the second viewport; and
a monitor for obtaining plasma light information on areas where plasma light transmitted through at least one of the first selective light blocking parts and plasma light transmitted through at least one of the second selective light blocking parts intersect, and monitoring uniformity of plasma formed in the chamber for each area based on the plasma light information.

2. The plasma process monitoring device according to claim 1, wherein the first selection area light transmitting part and the second selection area light transmitting part are arranged to form an angle of 0° to 180° with respect to each other.

3. The plasma process monitoring device according to claim 2, wherein the first selection area light transmitting part and the second selection area light transmitting part are arranged in a direction perpendicular or horizontal to each other, or are arranged to be inclined with respect to each other.

4. The plasma process monitoring device according to claim 1, wherein the first selection area light transmitting part is arranged in parallel with the first viewport disposed in a width direction of the chamber, and
the second selection area light transmitting part is arranged in parallel with the second viewport disposed in a thickness direction of the chamber.

5. The plasma process monitoring device according to claim 1, wherein the first selection area light transmitting part is provided with M first selective light blocking parts;
the second selection area light transmitting part is provided with N second selective light blocking parts; and
the monitor obtains plasma light information on M×N areas, and monitors uniformity of plasma formed in the chamber for each area based on the plasma light information.

6. The plasma process monitoring device according to claim 1, wherein the first selection area light transmitting part comprises a plurality of first selective light blocking parts arranged in parallel in a horizontal or vertical direction, and the second selection area light transmitting part comprises a plurality of second selective light blocking parts arranged in parallel in a horizontal or vertical direction.

7. The plasma process monitoring device according to claim 5, wherein the first selective light blocking parts and the second selective light blocking parts are each formed in a rectangular shape.

8. The plasma process monitoring device according to claim 1, wherein the first selection area light transmitting part and the second selection area light transmitting part each comprise a transparent LCD panel provided with one or more LCD unit panels, each of which is divided into at least one area and supplied with power individually, wherein plasma light is transmitted only through an area to which power is supplied, and
a switch connected to the transparent LCD panel and responsible for selectively supplying power to each of areas of each of the LCD unit panels.

9. The plasma process monitoring device according to claim 1, wherein the first selection area light transmitting part and the second selection area light transmitting part each comprise a frame having an opening formed therein, and
a plurality of shutter members arranged in a line in the frame and responsible for selectively shielding a specific area of the opening.

10. The plasma process monitoring device according to claim 1, wherein the first selection area light transmitting part and the second selection area light transmitting part each comprise a plurality of polarization filter sets, each polarization filter set comprising two or more polarization filters arranged so as to overlap each other, and configured to selectively transmit plasma light, and
a controller for controlling an arrangement angle of at least one of the polarization filters comprised in each of the polarization filter sets so that plasma light incident on the polarization filter set is selectively blocked.

11. The plasma process monitoring device according to claim 1, wherein the first selection area light transmitting part and the second selection area light transmitting part are integrally formed on one surface of the first viewport and one surface of the second viewport, respectively.

12. The plasma process monitoring device according to claim 1, wherein the plasma light information comprises an intensity or quantity of plasma light in areas where plasma light intersects.

13. The plasma process monitoring device according to claim 12, wherein the monitor receives information on an intensity or quantity of plasma light in areas where plasma light intersects, determines whether the intensity or quantity of plasma light falls within a predetermined range, and determines uniformity of plasma formed in the chamber for each area.

14. The plasma process monitoring device according to claim 1, wherein the monitor comprises an optical fiber or a measurement sensor to monitor an intensity or quantity of plasma light.

15. The plasma process monitoring device according to claim 1, wherein the monitor comprises an optical emission spectrometer (OES) or a camera.

16. The plasma process monitoring device according to claim 1, wherein the first selection area light transmitting part and the second selection area light transmitting part are each connected to a separate monitor or are connected to one common monitor.

17. The plasma process monitoring device according to claim 1, wherein the first selection area light transmitting part and the second selection area light transmitting part each further comprise a light collector for expanding and focusing an angle of incidence range of plasma light emitted from an inside of the chamber and providing the plasma light to the monitor.

18. A plasma processing apparatus, comprising:
a chamber in which a plasma process is performed;
first and second viewports for emitting plasma light generated in the chamber, wherein the first viewport is disposed on one side of the chamber and the second viewport is disposed on the other side of the chamber;
a first selection area light transmitting part disposed to face the first viewport, and provided with a plurality of first selective light blocking parts for selectively blocking plasma light emitted through the first viewport;
a second selection area light transmitting part disposed to face the second viewport, and provided with a plurality of second selective light blocking parts for selectively blocking plasma light emitted through the second viewport; and
a monitor for obtaining plasma light information on areas where plasma light transmitted through at least one of the first selective light blocking parts and plasma light transmitted through at least one of the second selective light blocking parts intersect, and monitoring uniformity of plasma formed in the chamber for each area based on the plasma light information.

19. The plasma processing apparatus according to claim 18, wherein the first selection area light transmitting part and the second selection area light transmitting part are arranged to form an angle of 0° to 180° with respect to each other.

20. The plasma processing apparatus according to claim 19, wherein the first selection area light transmitting part is arranged in parallel with the first viewport disposed in a width direction of the chamber, and
the second selection area light transmitting part is arranged in a vertical or horizontal direction with respect to the first selection area light transmitting part, or the second selection area light transmitting part and the first selection area light transmitting part are arranged to be inclined with respect to each other.
